(19) United States
(12) Patent Application Publication
(10) Pub. No.: US 2009/0314947 A1
(43) Pub. Date: Dec. 24, 2009

(54) Radiation Detector with Isolated Pixels Photosensitive Array for CT and Other Imaging Applications

(75) Inventors: Alexander O. Goushcha, Aliso Viejo, CA (US); Perry A. Denning, Irvine, CA (US); Frederick A. Flitsch, New Windsor, NY (US)

Correspondence Address: BLAKELY SOKOLOFF TAYLOR & ZAFMAN LLP, 1279 OAKMEAD PARKWAY, SUNNYVALE, CA, 94085-4040, US

(73) Assignee: ARRAY OPTRONIX, INC., Costa Mesa, CA (US)

(21) Appl. No.: 12/475,274

(22) Filed: May 29, 2009

Related U.S. Application Data
(60) Provisional application No. 61/057,603, filed on May 30, 2008.

(51) Int. Cl. G01T 1/20; H01L 31/14

(52) U.S. Cl. 250/363.01; 250/367; 257/443; 250/371; 257/446; 257/E31.097

(57) ABSTRACT

This invention describes an imaging system based on an array of semiconductor photosensitive elements with isolating structure between elements (pixels) of the array. The isolated pixels of the array may be photodiodes and they provide excellent imaging capabilities that are important for many applications. The isolated photosensitive pixels may be comprised also by photoconductors, avalanche photodiodes, photosensitive IC, or other similar solid-state devices. The fields of possible application include but are not limited to the detector modules for homeland security, medical imaging systems (CT, SPECT, and PET including), fundamental and applied research, etc.

### CROSS-REFERENCE TO RELATED APPLICATION

This application claims the benefit of U.S. Provisional Patent Application No. 61/057,603 filed May 30, 2008.

### BACKGROUND OF THE INVENTION

1. Field of the Invention

The present application relates to an imaging system in which radiation is received and then converted into electron-hole pairs by radiation-sensitive semiconductor detectors.

2. Prior Art

In many imaging applications, 1D or 2D detector arrays are used. In the case of 2D detectors the term “slice” is used to describe a detector row in the direction perpendicular to the scanned object (z-axis). The invention may be useful for medical imaging systems, such as CT, SPECT, PET scanners, and x-ray fluorography, as well as for other applications like baggage inspection and similar security systems.

As an example, a multi-slice x-ray detector may be composed of a series of individual pixels in the z-axis (slices) and a series of individual pixels in the x-axis (called channels). Each individual pixel may be composed of a scintillating crystal coupled to a primary photodetector. See FIG. 1 as an example, in which the photodiode array is used as a primary photodetector. The x-ray deposited in the scintillator pixel is converted to visible light. The light quanta generated in the scintillator are then propagated up to the surface of the primary photodetector where they are absorbed and converted to electron-hole charge.

In a different application a uniform (or quasi-uniform) scintillator material is deposited on an array of primary semiconductor photodetectors (FIG. 2). The uniform (quasi-uniform) scintillator material may be a film, a polycrystalline structure, or other micro-crystalline material. The scintillator material is not specified herein.

The electrical signal of each primary semiconductor photodetector pixel is individually routed to a corresponding pre-amplifier channel. The pre-amplifiers (or other readout electronics) may be attached to the primary photodetector array either directly (FIG. 3) or via the substrate with the re-routed signals from each individual pixel (FIG. 4). The further connection to the data acquisition system is made in one of the common for the industry ways.

Many imaging applications, including CT, SPECT, and PET scanners require clear separation of signals between adjacent pixels. However, the primary photodetector arrays used in the contemporary imaging systems do not provide good isolation between pixels. The electrical and optical crosstalk is imminent in such systems, which significantly deteriorate the image quality. To handle this problem, sophisticated filtering has to be applied, which could not solve the problem completely anyway. See U.S. Pat. Nos. 6,426,991, 6,510,195, 6,760,404, 7,003,076 and 7,439,516.

Recently, the light-sensitive primary photodetector (photodiode) array having isolated pixels was described in U.S. Pat. Nos. 6,762,473 and 7,112,465, U.S. Patent Application Publication No. 2005/0221541 and U.S. patent application Nos. 11,368,041, 11/636,026, 11/811,121, 11/786,385 and 12/188,829 the disclosures of which are hereby incorporated herein by reference.

Such primary photodetector arrays with isolated pixels are characterized with a very low electrical crosstalk between adjacent pixels. The optical crosstalk is also reduced significantly in imaging systems with such isolated pixel arrays. As a result, a less noisy and higher quality image can be obtained using imaging systems with isolated primary photodetector pixels. Moreover, less noisy signals require less exposure time and consequently less total radiation dose to a subject to obtain an image of the same quality. These findings are especially important for medical imaging applications. These topics were discussed thoroughly in a series of our recent publications. See “Silicon PIN Photodiode Array for Medical Imaging Applications: Structure, Optical Properties and Temperature Coefficients” (Goushcha et al., IEEE Nuclear Science Symposium Conference Record, 2005), “Temperature coefficients and noise performance and studies for the back-illuminated arrays for medical imaging applications” (Goushcha et al., Proceedings of SPIE, 2006, Vol. 6142) and “Optical and Electrical Crosstalk in PIN Photodiode Array for Medical Imaging Applications” (Goushcha et al., “IEEE Nuclear Science Symposium Conference Record, 2007), the disclosures of which are hereby incorporated herein by reference.

The present invention contemplates an apparatus and method to incorporate a primary photodetector with isolated pixels in imaging systems and their subcomponents, including CT, PET, and SPECT scanners. The invention allows overcoming many of the above listed problems and to build imaging systems with less noise, higher imaging quality, and potentially lower exposure dose.

### BRIEF DESCRIPTION OF THE DRAWINGS

FIG. 1 (prior art), schematically illustrates a cross section of a conventional detector array consisting of the array of back-illuminated primary photodetectors (e.g. photodiodes) and attached pixilated scintillator array.

FIG. 2 (prior art) schematically illustrates a cross section of a conventional detector array consisting of the array of back-illuminated primary photodetectors (e.g. photodiodes) and attached or deposited uniform (or quasi-uniform) scintillator material 202.

FIG. 3 (prior art) illustrates that the electrical signal of each primary photodetector pixel is individually routed to a corresponding pre-amplifier channel on a readout electronics chip.

FIG. 4 (prior art) schematically illustrates that each pixel of the primary photodetector array is attached to the pre-amplifier and other readout electronics chip 420 via the substrate 410, which uses re-routed signals from the primary photodetector array.

FIG. 5 schematically illustrates a main concept of the present invention, in which the primary photodetector of the imaging system is the array of isolated photosensitive pixels.

FIG. 6 schematically illustrates a radiation detector in which the scintillator material of the imaging system is the uniform (or quasi-uniform) scintillator material.

FIG. 7 schematically illustrates a direct conversion imaging detector, in which the detector of the imaging system does not have a scintillator attached to the isolated pixels primary photodetector array 520.

FIG. 8 schematically illustrates another embodiment of the present invention, in which the electrical signal from each isolated pixel of the primary photodetector is individually routed to a corresponding pre-amplifier channel on a readout electronics chip.

FIG. 9 schematically illustrates another embodiment, in which each isolated pixel of the primary photodetector array is attached to the pre-amplifier and other readout electronics chip or substrate (layer) via the substrate (layer), which uses individual re-routed signals from the isolated pixels of the primary photodetector array.

FIG. 10 shows schematically another embodiment, in which a switch for selecting a photosensitive element of the array and a data acquisition chip are shown as parts of either or both substrates (layers) attached to the primary photodetector array.

FIG. 11 schematically illustrates another embodiment, in which the substrate attached to the primary photodetector array consists of the two substrate layers, the first disposed parallel to the photodetector array and the second disposed perpendicular to and in support of the first substrate layer.

### DETAILED DESCRIPTION OF THE PREFERRED EMBODIMENTS

In one embodiment of the invention, the imaging system for medical imaging or other applications includes a radiation sensitive detector with a pixellated scintillator array optically coupled to the isolated pixels semiconductor photo-sensitive device (primary photodetector). A plurality of isolated pixels of the semiconductor photodetector array is connected to the readout electronics either by directly contacting the pre-amplifiers or via routings through the support substrate. The connection to the readout electronics may be provided on either side of the isolated pixels primary photodetector array.

In accordance with another embodiment, the isolated pixels of the primary photodetector are connected individually to the first polarity electrodes and further to the readout electronics of the imaging system. The isolation area between pixels may be connected to the opposite polarity electrode of the readout electronics.

In accordance with another embodiment of the present invention, the isolation between the pixels of semiconductor devices of the imaging system is made by the matrix of through diffusions of the same polarity dopants as the substrate. The diffusions can penetrate through the whole thickness of the primary photodetector array. The through diffusion areas may not necessarily be of uniform concentration across the whole thickness of the semiconductor device.

In accordance with another embodiment of the present invention, the isolated pixels of the semiconductor array are separately connected to the readout electronics either by direct contacting the pre-amplifiers or via the routing through the support substrate.

In accordance with another embodiment of the present invention the isolated photodetector pixels can be photodiodes.

In accordance with another embodiment of the present invention the isolated photodetector pixels can be photoconductors.

In accordance with the other embodiment the isolated pixels of a primary photodetector can be avalanche photodiodes or silicon photomultipliers.

In accordance with another embodiment of the present invention each isolated pixel of a primary photodetector that is a part of imaging system can contain an integrated pre-amplifier.

In accordance with another embodiment of the present invention the whole detector module with isolated pixel primary photodetector array is used as a detector for the medical imaging system, such as CT, SPECT, PET, or similar.

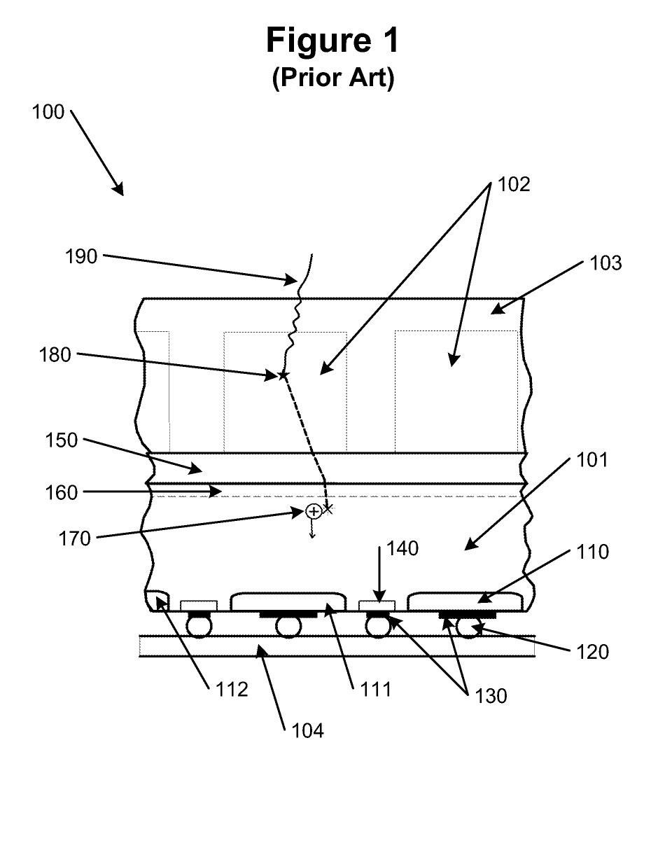

FIG. 1 (prior art), item 100, exemplifies schematically a cross section of a conventional detector array consisting of the array of primary photodetectors (e.g. photodiodes) and attached pixilated scintillator array. In particular, FIG. 1 shows the back-illuminated primary photodiode array 101.

The primary photodetector array 101 is an array of photo-sensitive elements, each converting the optical quanta into electrical signal. The features and structure of the primary photodetector array are not the embodiments of the current invention. FIG. 1 shows a conventional back-illuminated photodiode array 101 as an example of a primary photodetector array. 110, 111, and 112 are anodes of the elements of the primary photodetector array, 140 are the cathode contact diffusions, 160 is the cathode backside diffusion, 130 are the metal pads, and 120 are the solder balls or stud bumps. The photosensitive pixels of the primary photodetector array 101 in FIG. 1 are not isolated.

The trenches (gaps) between scintillator pixels 102 may be filled with epoxy containing reflective particles (for example TiO2), item 103 in FIG. 1. The epoxy provides also mechanical integrity to the whole scintillator array, keeping the scintillator pixels together. X-ray photons 190 are deposited on scintillator array creating optical photons 180. The optical photons 180 generated inside the scintillator pixels 102 travel towards the primary photodetector 101 and create electron-hole pairs 170 via absorption mechanism, generating electrical signal in the elements of the primary photodetector array. In FIG. 1, the primary photodetector array is attached to the printed circuit board 104 and electrical signals from each isolated pixel are routed via PCB 104 to the readout electronics (not shown in FIG. 1).

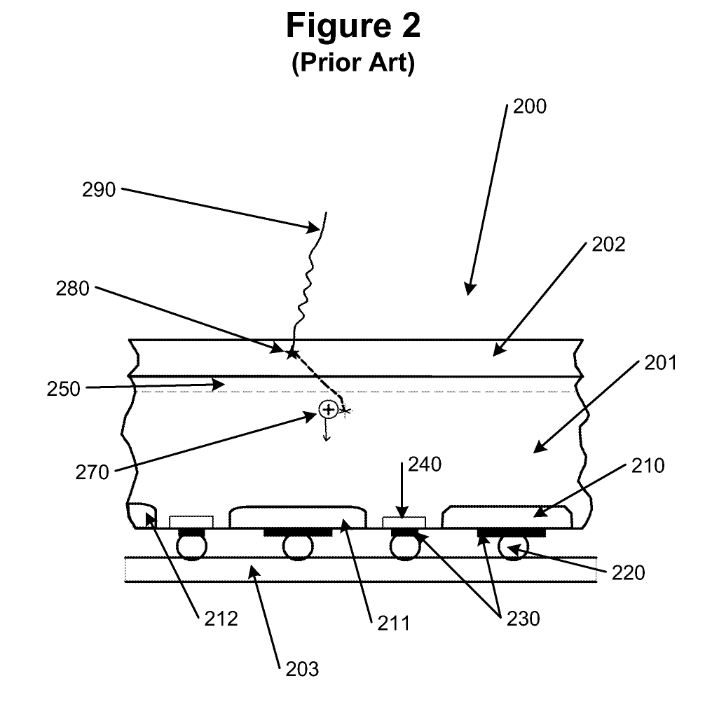

FIG. 2 (prior art), item 200, exemplifies schematically a cross section of a conventional detector array consisting of the array of primary photodetectors (e.g. photodiodes) and attached or deposited uniform (or quasi-uniform) scintillator material 202. In Particular, FIG. 2 shows the back-illuminated primary photodiode array 201, which may be similar to the item 101 in FIG. 1. 210, 211, and 212 are anodes of the elements of the primary photodetector array, 240 are the cathode contact diffusions, 250 is the cathode backside diffusion, 230 are the metal pads, and 220 are the solder balls or stud bumps. The scintillator material 202 may be coupled to the primary photodetector array 201 using optical cement (not shown in FIG. 2). Alternatively, the scintillator material may be directly deposited in the surface of the photodetector array. The photosensitive pixels of the primary photodetector array 201 in FIG. 2 are not isolated.

X-ray photons 290 are deposited in scintillator material 202 creating optical quanta 280, which travel towards the primary photodetector 201 and create electron-hole pairs 270 via absorption mechanism.

In FIG. 2, the primary photodetector array 201 is attached to the printed circuit board 203 and electrical signals from each isolated pixel are routed via PCB 203 to the readout electronics (not shown in FIG. 2).

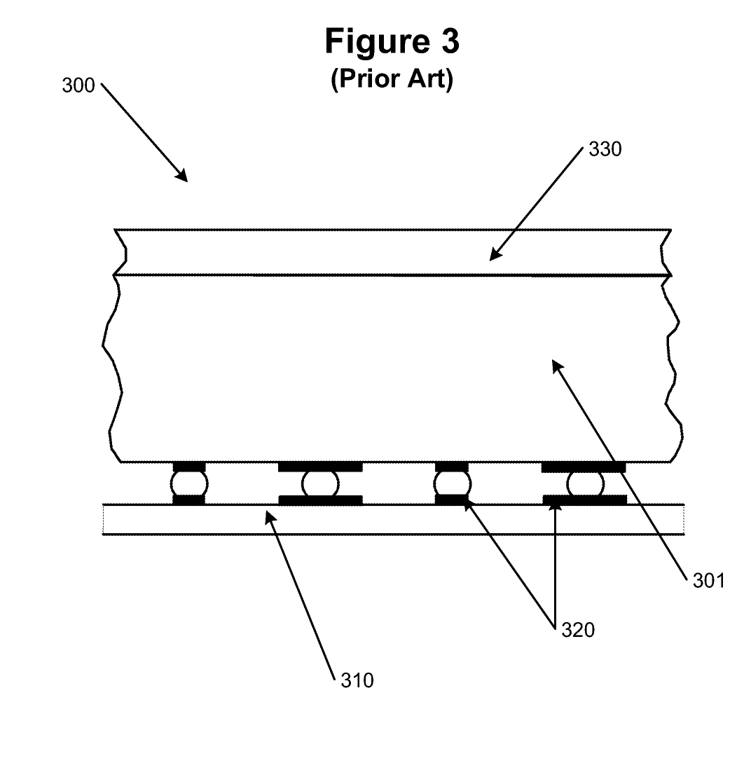

In FIG. 3 (prior art), item 300, the electrical signal of each primary photodetector pixel is individually routed to a corresponding pre-amplifier channel on a readout electronics chip 310. The readout electronics (pre-amplifier) chip is attached to the primary photodetector array 301 directly. 320 are the metal pads on the chip 310. 330 is the scintillator material, which may be the same as item 102 in FIG. 1 or item 202 in FIG. 2. In the prior art, the primary photodiode array 301 consisted of not isolated pixels.

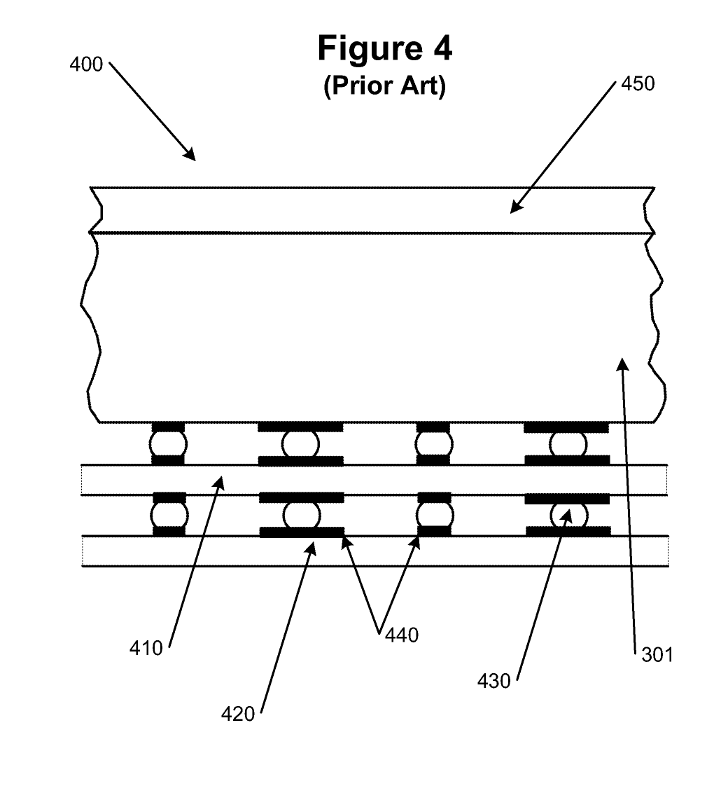

In FIG. 4 (prior art), item 400, each pixel of the primary photodetector array 301 is attached to the pre-amplifier and other readout electronics chip 420 via the substrate 410, which uses re-routed signals from the primary photodetector array 301. The substrate 410 may be either PCB or ceramic, or other known in the industry substrate. The further connection to the data acquisition system is made in one of the common for the industry ways. 440 are the contact pads on the chip 420. 430 are the solder balls or studs on the contact pads. The scintillator material 450 may be the same as item 330 in FIG. 3. The photosensitive pixels of the primary photodetector array 301 in FIG. 4 are not isolated.

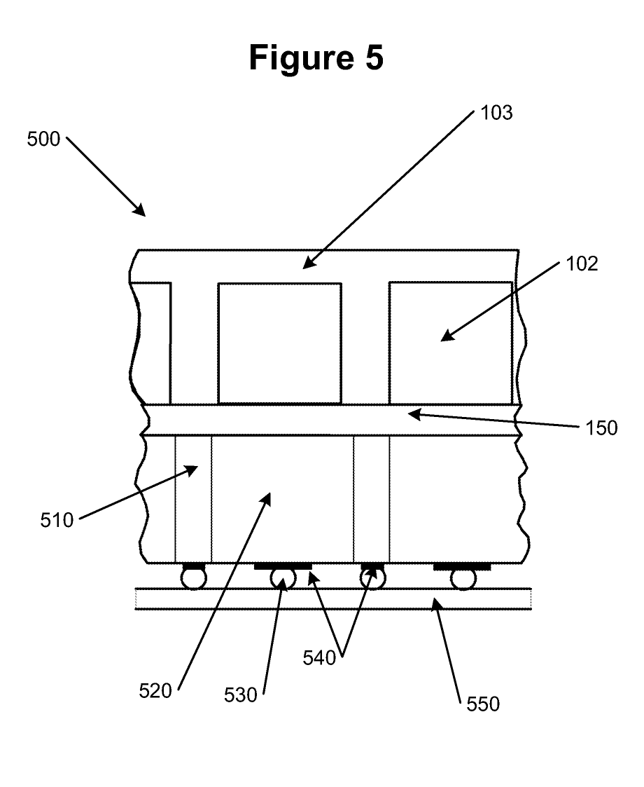

FIG. 5 demonstrates the main idea of the current invention, in which the primary photodetector 520 of the imaging system is an array of isolated photosensitive pixels. The isolation structures 510 between pixels of the array may span across the whole thickness of the semiconductor crystal that forms the primary photodetector array 520. The isolation structures 510 may consist either partially or completely of diffusion of n- or p-type. The diffusions 510 may be of the same conductivity type as the semiconductor substrate. Diffusions 510 may not necessarily be uniform in concentration across the semiconductor crystal thickness. The doping concentration in the diffusion region may be at least one order of magnitude higher than the doping concentration of the semiconductor material used to manufacture the primary photodetector array. The pixilated scintillator array may in some embodiments be attached to the primary photodetector array using optical coupler 150. Pixels 102 of the scintillator array may be separated from each other with a reflective material (septa) 103. Metal pads 540 used to contact the downstream electronics on a ceramic or PCB support substrate 550 via the solder balls or studs 530. The downstream electronics may contain a data acquisition chip for acquiring data output from the array of photosensitive elements and a switch for selecting elements of the array.

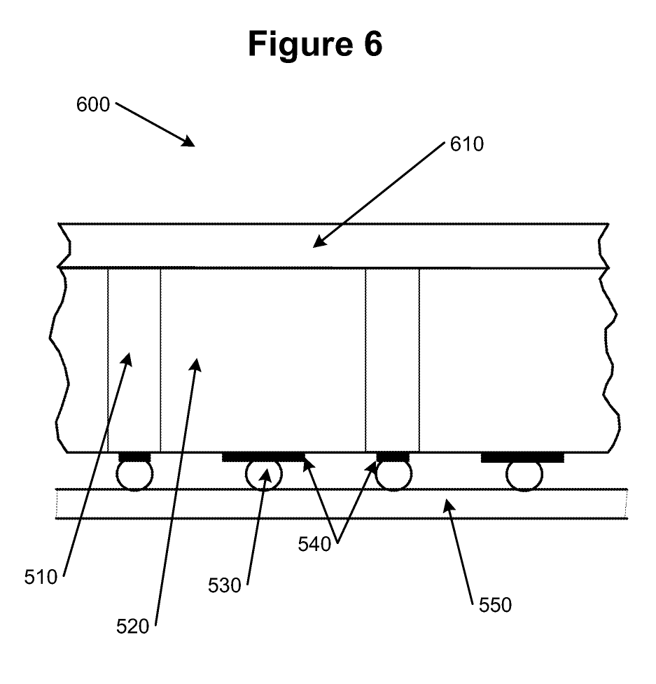

FIG. 6, item 600, describes one of the ideas of the current invention, in which the scintillator material 610 of the imaging system may be a uniform (or quasi-uniform) scintillator material. The scintillator material may be coupled to the primary photodetector array 520 with optical coupler (not shown in FIG. 6). Alternatively, the scintillator material may be directly deposited on the surface of the isolated pixel primary photodetector array. The photosensitive pixels of the primary photodetector array 520 in FIG. 6 are isolated from each other by the through structures 510. The structures 510 may be formed by the diffusions that penetrate through the semiconductor substrate from either both surfaces or one surface of the said semiconductor substrate. Such diffusions 510 may not necessarily be uniform across the array thickness. As in the previous case of FIG. 5, the doping concentration in the diffusion region 510 may be at least one order of magnitude higher than the doping concentration of the semiconductor material used to manufacture the isolated pixels primary photodetector array.

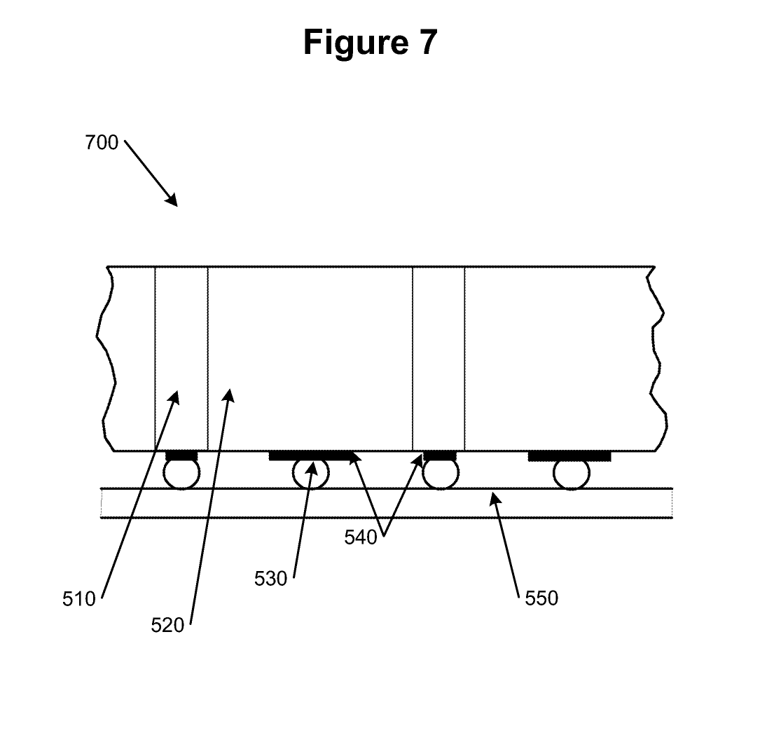

FIG. 7, item 700, describes another idea of the current invention, in which the detector of the imaging system may not have a scintillator attached to the isolated pixels primary photodetector array 520. This is a direct conversion imaging detector.

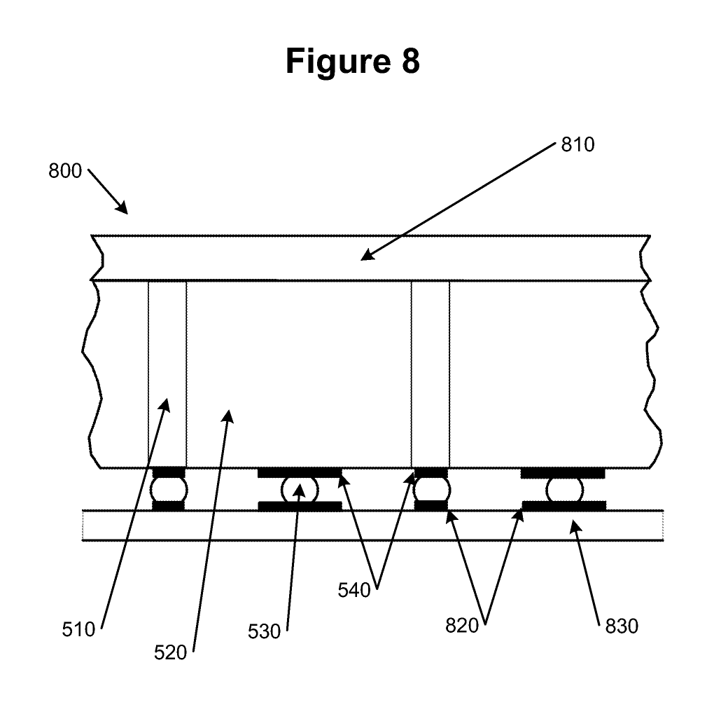

FIG. 8, item 800, describes another embodiment of the current invention, in which the electrical signal from each isolated pixel of the primary photodetector array may be individually routed to a corresponding pre-amplifier channel on a readout electronics chip or substrate layer 830. The readout electronics (pre-amplifier) chip is attached to the primary photodetector array directly using bonding pads 820 on the readout electronics chip. The readout electronics chip 830 may contain a data acquisition chip for acquiring data output from the array of photosensitive elements and a switch for selecting elements of the array. Item 810 can be either a pixilated scintillator array like item 102 in FIG. 5 or a (quasi)uniform scintillator material like item 610 in FIG. 6. Item 810 is coupled to the isolated pixels primary photodetector array. The scintillator material 810 may be coupled to the primary photodetector array 520 with an optical coupler (not shown in FIG. 8) or it can be deposited on the surface of the array 520.

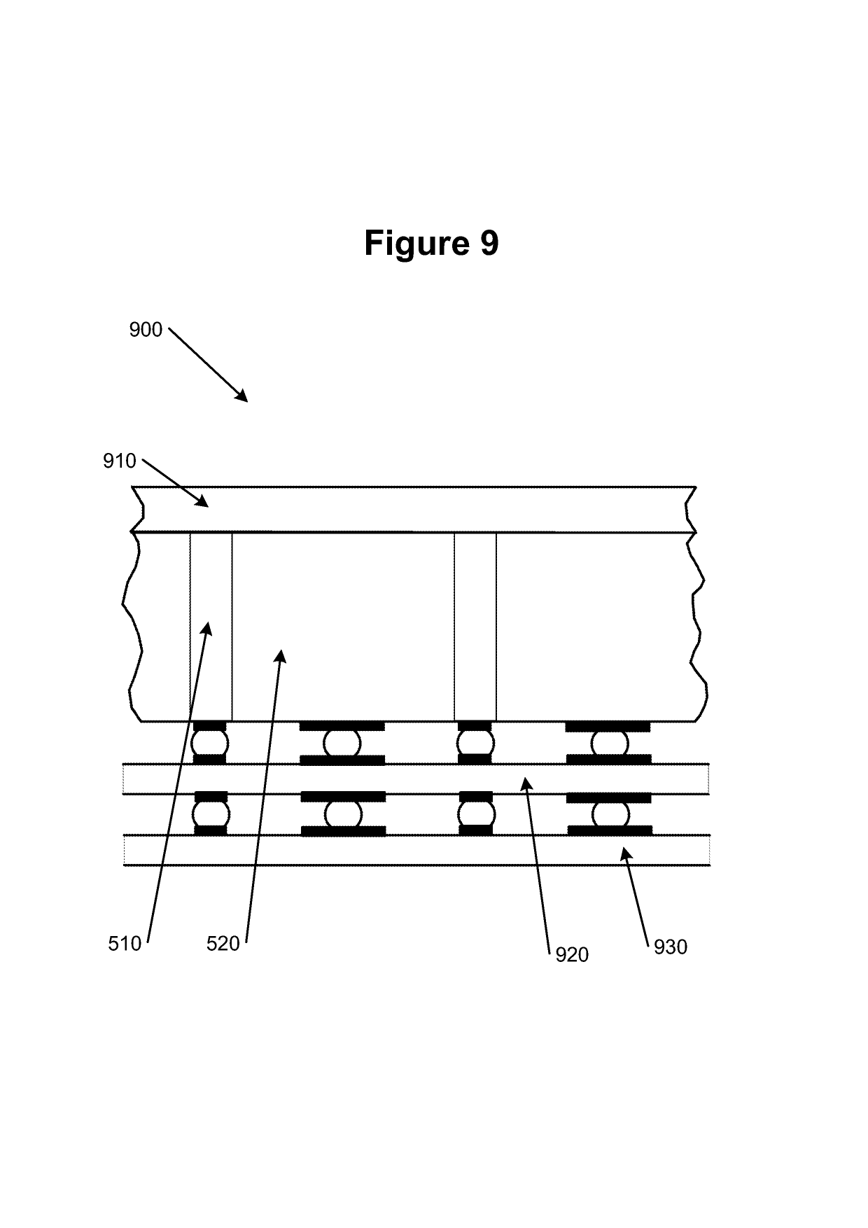

FIG. 9, item 900, describes another embodiment, in which each isolated pixel of the primary photodetector array 520 is attached to the pre-amplifier and other readout electronics chip or support substrate layer 930 via the support substrate 920, which uses individual re-routed signals from the isolated pixels of the primary photodetector array 520. The readout electronics may contain a data acquisition chip for acquiring data output from the array of photosensitive elements and a switch for selecting elements of the array. The support substrate 920 may be either PCB or ceramic, or other known in the industry substrate. The further connection to the data acquisition system is made in one of the common for the industry ways. Item 910 is a scintillator material, which may be the same as item 810 in FIG. 8. Note that the detector of the imaging system may not have a scintillator at all. In this case each isolated diffusion pixel of the primary photodetector array performs as a direct conversion primary detector.

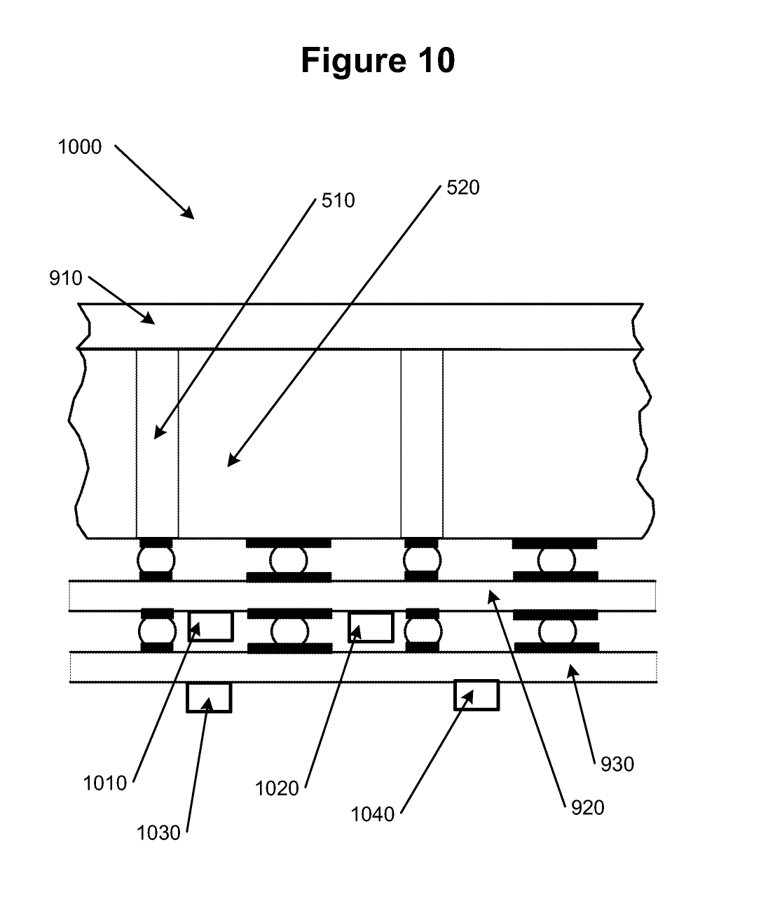

FIG. 10, item 1000, shows another embodiment of the invention, in which a switch 1010 for selecting a photosensitive element of the array and a data acquisition chip 1020 are shown as parts upon the first support substrate (layer) 920. A switch 1030 and a data acquisition chip 1040 may be parts upon the second support substrate (layer) 930.

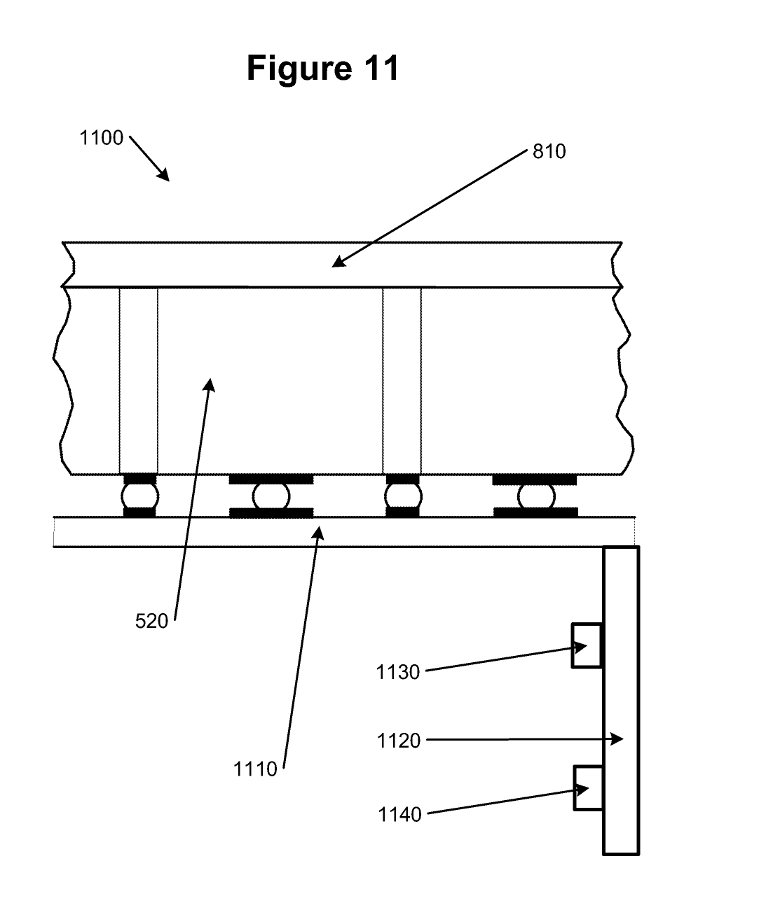

In still another embodiment, FIG. 11, item 1100, the support substrate that may be attached to the primary photodetector array may consists of two support substrate layers, the first, item 1110, disposed parallel to the photodetector array 520 and the second, item 1120, disposed at any angle to and in support of the first support substrate layer 1110. In FIG. 11 the second support substrate, item 1120 is shown perpendicular to the first support substrate 1110 however it should be obvious to one skilled in the arts that in fact item 1120 may be deployed at some angle other than 90 degrees relative to the first support substrate 1110. The first support substrate layer 1110 may be the same as item 920 in FIG. 9. As well, for reference, there may be electronic switches, 1130 and data acquisition chips 1140 on this embodiment as well.

While certain preferred embodiments of the present invention have been disclosed and described herein for purposes of illustration and not for purposes of limitation, it will be understood by those skilled in the art that various changes in form and detail may be made therein without departing from the spirit and scope of the invention.

What is claimed is:

1. A radiation detection system comprising:
a photo-sensitive device having multiple photo-sensitive elements arrayed upon a semiconductor substrate with isolation surrounding the periphery of each of said multiple elements, wherein said isolation propagates between a first, top surface and a second, back surface of the semiconductor substrate;
a plurality of scintillator elements which convert x-ray radiation into light, attached to a surface of the semiconductor substrate and aligned with the multiple elements thereupon; and,
at least one electrical amplification element which electrically contacts said multiple elements, wherein said amplification element is affixed to a support substrate in contact with a surface of the semiconductor substrate.

2. The radiation detection system of claim 1 wherein the semiconductor substrate surface in contact with the scintillator elements is free of electrical contacts.

3. A radiation detector array comprising:
a radiation sensitive surface which converts received radiation into photons of light;
a photodiode array that comprises a semiconductor substrate of a first conductivity type having first and second surfaces, the second, back surface being free of electrical contacts in optical communication with the radiation sensitive surface, and which photodiode array generates electrical signals responsive to the photons of light generated by the radiation sensitive surface, the second surface having a layer of the first conductivity type having a greater conductivity than the semiconductor substrate;
a matrix of regions of a first conductivity type of a higher conductivity than the semiconductor substrate extending from the first surface of the semiconductor substrate to the layer of the first conductivity type having a greater conductivity than the said semiconductor substrate, wherein the entire matrix regions are semiconductor doped regions;
a plurality of regions of the second conductivity type interspersed within the matrix of regions of the first conductivity type and not extending to the layer of the first conductivity type on the second surface of the semiconductor substrate;
a plurality of contacts on the first surface for making electrical contact to the matrix of regions of the first conductivity type and the plurality of regions of the second conductivity type;
and which has its contacts arranged on a first, top surface opposite the second, back surface, and a support substrate supporting the photodiode, the support substrate configured to provide an electrical path from the contacts on the first surface of the photodiode through the support substrate.

4. A radiation detector array comprising:
a radiation sensitive surface which converts received radiation into photons of light;
a photodiode array that comprises a semiconductor substrate of a first conductivity type having first and second surfaces, the second, back surface in optical communication with the radiation sensitive surface, which generates electrical signals responsive to the photons of light generated by the radiation sensitive surface, the second surface having a layer of the first conductivity type having a greater conductivity than the said semiconductor substrate;
a first matrix of regions of a first conductivity type of a higher conductivity than the semiconductor substrate extending into the semiconductor substrate from the first surface of the said semiconductor substrate;
a second matrix of regions of a first conductivity type of a higher conductivity than the semiconductor substrate extending into the said semiconductor substrate from the second surface of the semiconductor substrate and aligned with the first matrix, the first and second matrices not extending into the said semiconductor substrate to touch each other;
a plurality of regions of the second conductivity type interspersed within the first matrix of regions of the first conductivity type on the first surface of the semiconductor substrate and not extending to the layer of the first conductivity type on the second surface of the said semiconductor substrate;
a plurality of contacts on the first surface of a semiconductor substrate for making electrical contact to the matrix of regions of the first conductivity type and the plurality of regions of the second conductivity type;
and which has its signal contacts arranged on a first, top surface opposite the second, back surface of the semiconductor substrate; and
a support substrate supporting the photodiode, the support substrate configured to provide an electrical path from the contacts on the first surface of the photodiode through the support substrate.

5. A radiation detector array comprising:
a radiation sensitive surface which converts received radiation into photons of light;
a photodiode which has a second, back surface that includes electrical contacts, useful for testing, but not electrically connected other than for testing in optical communication with the radiation sensitive surface, which generates electrical signals responsive to the photons of light generated by the radiation sensitive surface, and which has its electrically connected signal contacts arranged on a first, top surface opposite the second, back surface;
and a support substrate supporting the photodiode, the support substrate configured to provide an electrical path from the contacts on the first, top surface of the photodiode through the support substrate.

6. The radiation detector array of claim 5:
wherein the photodiode is configured into a photodiode array,
wherein the photodiode array comprises a semiconductor substrate of a first conductivity type having first and second surfaces;
the second surface having a layer of the first conductivity type having a greater conductivity than the semiconductor substrate;
a matrix of regions of a first conductivity type of a higher conductivity than the said semiconductor substrate extending from the first surface of the semiconductor substrate to the layer of the first conductivity type having a greater conductivity than the semiconductor substrate, wherein the entire matrix regions are semiconductor doped regions;
a plurality of regions of the second conductivity type interspersed within the matrix of regions of the first conductivity type and not extending to the layer of the first conductivity type on the second surface of the semiconductor substrate; and,
a plurality of contacts on the first surface for making electrical contact to the matrix of regions of the first conductivity type and the plurality of regions of the second conductivity type;

7. A method comprising:
illuminating a radiation sensitive surface with x-rays;
converting the x-rays illuminating the radiation sensitive surface into light;
producing an electrical signal proportional to the converted light with a photodiode array wherein said photodiode array comprises a semiconductor substrate of a first conductivity type having first and second surfaces;
the second surface having a layer of the first conductivity type having a greater conductivity than the semiconductor substrate;
a matrix of regions of a first conductivity type of a higher conductivity than the semiconductor substrate extending from the first surface of the said semiconductor substrate to the layer of the first conductivity type having a greater conductivity than the semiconductor substrate, wherein the entire matrix regions are semiconductor doped regions;
a plurality of regions of the second conductivity type interspersed within the matrix of regions of the first conductivity type and not extending to the layer of the first conductivity type on the second surface of the semiconductor substrate;
a plurality of contacts on the first surface for making electrical contact to the matrix of regions of the first conductivity type and the plurality of regions of the second conductivity type; and,
communicating the electrical signal through a support substrate to processing circuitry sheltered from the x-rays via a path orthogonal to the radiation sensitive surface.

8. A method comprising:
illuminating a radiation sensitive surface with x-rays;
converting the x-rays illuminating the radiation sensitive surface into light;
producing an electrical signal proportional to the converted light with a photodiode array wherein said photodiode array comprises a semiconductor substrate of a first conductivity type having first and second surfaces;
the second surface having a layer of the first conductivity type having a greater conductivity than the semiconductor substrate;
a first matrix of regions of a first conductivity type of a higher conductivity than the semiconductor substrate extending into the said semiconductor substrate from the first surface;
a second matrix of regions of a first conductivity type of a higher conductivity than the semiconductor substrate extending into the said semiconductor substrate from the second surface of the semiconductor substrate and aligned with the first matrix, the first and second matrices not extending into the semiconductor substrate to touch each other;
a plurality of regions of the second conductivity type interspersed within the first matrix of regions of the first conductivity type on the first surface of the semiconductor substrate and not extending to the layer of the first conductivity type on the second surface of the said semiconductor substrate;
a plurality of contacts on the first surface for making electrical contact to the matrix of regions of the first conductivity type and the plurality of regions of the second conductivity type; and,
communicating the electrical signal through a support substrate to processing circuitry sheltered from the x-rays via a path orthogonal to the radiation sensitive surface.

9. A radiation detection system comprising:
a scintillator block for converting X-rays into light;
a photo-sensitive device having multiple photo-sensitive elements arrayed upon a semiconductor substrate with isolation surrounding the periphery of each of said multiple elements, wherein said isolation propagates between a first, top surface and a second, back surface of the semiconductor substrate;
a plurality of contacts on the first surface for making electrical contact to the plurality of photosensitive elements and to the isolation regions;
communicating the electrical signal through a first support substrate to processing circuitry sheltered from the x-rays via a path orthogonal to the radiation sensitive surface;
a processing circuitry or readout electronics formed on a chip or second support substrate attached to the first support substrate;
a switch for selecting a photodiode, from said photodiode array, from which an electrical signal is to be output;
a data acquisition chip for acquiring data output from said photodiode array selected by said switch; and
means for integrating said scintillator block, said photosensitive device, said support substrates, and said data acquisition, said switch and processing circuitry chip.

10. A radiation detection system comprising:
a scintillator block for converting X-rays into light;
a photodiode array for converting the light into electrical signals wherein said photodiode array comprises a semiconductor substrate of a first conductivity type having first and second surfaces;
the second surface having a layer of the first conductivity type having a greater conductivity than the semiconductor substrate;
a matrix of regions of a first conductivity type of a higher conductivity than the semiconductor substrate extending from the first surface of said semiconductor substrate to the layer of the first conductivity type having a greater conductivity than the semiconductor substrate, wherein the entire matrix regions are semiconductor doped regions;
a plurality of regions of the second conductivity type interspersed within the matrix of regions of the first conductivity type and not extending to the layer of the first conductivity type on the second surface of the semiconductor substrate;
a plurality of contacts on the first surface for making electrical contact to the matrix of regions of the first conductivity type and the plurality of regions of the second conductivity type;
communicating the electrical signal through a first support substrate to processing circuitry sheltered from the x-rays via a path orthogonal to the radiation sensitive surface;
a processing circuitry and readout electronics formed on a chip or second support substrate attached to the first support substrate;
a switch for selecting a photodiode, from said photodiode array, from which an electrical signal is to be output;
a data acquisition chip for acquiring data output from said photodiode array selected by said switch; and
means for integrating said scintillator block, said photodiode array, said support substrates for signal communication, and said data acquisition chip and switch.

11. An imaging system comprising:
an x-ray radiation source selectively generating a beam of x-ray radiation that traverses an examination region from a multiplicity of directions;
a radiation detector positioned opposite the examination region from the radiation source, the radiation detector comprising a photo-sensitive device having multiple photo-sensitive elements arrayed upon a semiconductor substrate with isolation surrounding the periphery of each of said multiple elements, wherein said isolation propagates between a first, top surface and a second, back surface of the substrate;
a plurality of contacts on the first surface of the semiconductor substrate for making electrical contact to the plurality of photosensitive elements and to the isolation regions;
a scintillation crystal overlaying the photodetector array for converting received x-ray radiation into light, the scintillation crystals being optically coupled to the elements of the photo-sensitive device;
a support substrate comprising a first support substrate layer disposed parallel to the photo-sensitive array and a second support substrate layer or chip disposed at any angle to and in support of the first support substrate layer; and,
a plurality of contacts and paths below the photo-sensitive array through the substrate, the paths providing electrical connectivity between the photodetectors and signal processing circuitry.

12. An imaging system comprising:
an x-ray radiation source selectively generating a beam of x-ray radiation that traverses an examination region from a multiplicity of directions,
a radiation detector array positioned opposite the examination region from the radiation source, the radiation detector array including a plurality of photodetectors arranged in an array, the photodetector array comprising a semiconductor substrate of a first conductivity type having first and second surfaces, the second surface having a layer of the first conductivity type having a greater conductivity than the substrate, a matrix of regions of a first conductivity type of a higher conductivity than the said semiconductor substrate extending from the first surface of the semiconductor substrate to the layer of the first conductivity type having a greater conductivity than the semiconductor substrate, wherein the entire matrix regions are semiconductor doped regions, a plurality of regions of the second conductivity type interspersed within the matrix of regions of the first conductivity type and not extending to the layer of the first conductivity type on the second surface of the semiconductor substrate, and a plurality of contacts on the first surface for making electrical contact to the matrix of regions of the first conductivity type and the plurality of regions of the second conductivity type;
a scintillation crystal overlaying the photodetector array for converting received x-ray radiation into light, the scintillation crystals being optically coupled to the primary photodetectors;
a support substrate comprising a first support substrate layer disposed parallel to the photodetector array and a second support substrate layer or chip disposed at any angle to and in support of the first support substrate layer; and,
a plurality of contacts and paths below the primary photodetector array through the substrate, the paths providing electrical connectivity between the photodetectors and signal processing circuitry.
